(19) United States
(12) Patent Application Publication
(10) Pub. No.: US 2021/0389623 A1
(43) Pub. Date: Dec. 16, 2021

(54) DISPLAY PANEL AND MANUFACTURING METHOD THEREOF

(71) Applicant: Wuhan China Star Optoelectronics Technology Co., Ltd., Wuhan (CN)

(72) Inventors: Fei AI, Wuhan (CN); Dewei SONG, Wuhan (CN)

(73) Assignee: Wuhan China Star Optoelectronics Technology Co., Ltd., Wuhan (CN)

(21) Appl. No.: 17/019,369

(22) Filed: Sep. 14, 2020

(30) Foreign Application Priority Data
Jun. 10, 2020 (CN) 202010524012.X

(51) Int. Cl. G02F 1/1339; H01L 27/12; H01L 29/786; H01L 29/66; G02F 1/1368; G02F 1/1335

(52) U.S. Cl. CPC G02F 1/13394; H01L 27/1222; H01L 29/78618; H01L 29/78633; H01L 29/78678; G02F 2001/133302; H01L 27/1288; H01L 29/66765; G02F 1/1368; G02F 1/133514; H01L 27/1274

(57) ABSTRACT

A display panel and a manufacturing method thereof are provided. The display panel includes: an array substrate with a first protrusion defined thereon; a color filter substrate disposed opposite to the array substrate; a supporting structure, wherein an end of the supporting structure is connected to a lateral side of the color filter substrate, another end of the supporting structure is connected to a lateral side of the array substrate, and the first protrusion is embedded into the supporting structure. The first protrusion is formed on a side of the array substrate near the color filter substrate. Therefore, when the supporting structure of the color filter substrate is aligned and attached to the array substrate, the first protrusion can be embedded into the supporting structure, thereby preventing the supporting structure from being moved. Thus, risk of alignment error is reduced, and abnormality of the display panel is prevented.

### RELATED APPLICATIONS

This application claims the benefit of priority of Chinese Patent Application No. 202010524012.X filed on Jun. 10, 2020, the contents of which are incorporated herein by reference in their entirety.

### FIELD

### Field and Background of the Invention

The present disclosure relates to the field of display technologies, and more particularly, relates to a display panel and a manufacturing method thereof.

Flat display devices, e.g., liquid crystal displays (LCDs), are widely used due to merits such as high resolution, low power consumption, thin and light body, and wide applications, and therefore have become mainstream display devices. Low temperature poly-silicon (LTPS) display technologies not only can prevent bright spots from appearing on panels, but also can increase resolution and reduce power consumption, which allows users to gain better visual experiences. To reduce manufacturing costs and production period of LTPS array substrates, an eight-mask process has been provided to realize LTPS array substrates with an in-cell touch function.

During manufacturing processes, photo spacers must be disposed on metal lines of a source/drain metal layer when a color filter substrate is attached. However, a planarization layer is omitted in the eight-mask process, resulting in a concave-convex surface of an array substrate. Therefore, positions of the metal lines of the source/drain metal layer are obvious. As a result, the photo spacers are easy to be moved from the source/drain metal layer, leading to a polyimide layer or other relevant layers being damaged, and contributing to abnormality of display panels.

### SUMMARY OF THE INVENTION

The present disclosure provides a display panel and a manufacturing method thereof to solve a following problem: in conventional display panels, photo spacers are easy to be moved from a source/drain metal layer, contributing to abnormality of the display panels.

In a first aspect, the present disclosure provides a display panel, including:

an array substrate with a first protrusion defined thereon;

a color filter substrate disposed opposite to the array substrate; and

a supporting structure disposed between the array substrate and the color filter substrate, wherein an end of the supporting structure is connected to a lateral side of the color filter substrate, and another end of the supporting structure is connected to a lateral side of the array substrate and abuts the first protrusion.

Furthermore, the array substrate further includes:

a glass substrate;

a buffer layer disposed on the glass substrate;

a thin-film transistor (TFT) layer disposed on the buffer layer; and

a passivation layer disposed on the TFT layer, wherein the first protrusion is defined on the passivation layer.

Furthermore,

the TFT layer includes:

an active layer;

a gate insulating layer disposed on the active layer;

a gate layer disposed on the gate insulating layer;

an interlayer dielectric layer disposed on the gate layer; and

a source/drain layer disposed on the interlayer dielectric layer.

Furthermore, a second protrusion is defined on the source/drain layer, and the passivation layer covers the source/drain layer, thereby forming the first protrusion on a position on the passivation layer corresponding to the second protrusion.

Furthermore, the gate layer includes a gate line and a third protrusion, and the source/drain layer covers the third protrusion, thereby forming the second protrusion on a position on the source/drain layer corresponding to the third protrusion.

Furthermore, a recess is defined on a side of the supporting structure near the array substrate and corresponds to the first protrusion, and the supporting structure abuts the array substrate by engaging the recess with the first protrusion.

Furthermore, the array substrate includes a gate layer and a source/drain layer, the source/drain layer is disposed on the gate layer, and the first protrusion is defined on the source/drain layer.

Furthermore, the first protrusion has a criss-crossing structure.

In a second aspect, the present disclosure further a method of manufacturing a display panel, including following steps:

forming a first protrusion on the array substrate;

providing a color filter substrate;

disposing a supporting structure on a side of the color filter substrate near the array substrate; and

aligning and attaching the color filter substrate to the array substrate, wherein an end of the supporting structure is connected to a lateral side of the color filter substrate, and another end of the supporting structure is connected to a lateral side of the array substrate and abuts the first protrusion.

Furthermore, the step of forming the first protrusion on the array substrate, including following steps:

providing a glass substrate;

forming a buffer layer on the glass substrate;

forming a gate layer on the buffer layer, wherein the gate layer includes a gate line and a second protrusion;

forming a source/drain layer on the second protrusion, thereby forming the first protrusion on the source/drain layer.

Embodiments of the present disclosure provide a display panel and a manufacturing method thereof. In the display panel, a first protrusion is formed on a side of an array substrate near a color filter substrate. As a result, when a supporting structure of a color filter substrate is aligned and attached to the array substrate, the first protrusion can be embedded into the supporting structure, thereby preventing the supporting structure from being moved. Therefore, risk of alignment error is reduced, and abnormality of the display panel is prevented.

### BRIEF DESCRIPTION OF THE SEVERAL VIEWS OF THE DRAWINGS

Technical solutions and beneficial effects of the present disclosure are illustrated below in detail in conjunction with drawings and specific embodiments.

FIG. 1 is a sectional schematic view showing a display panel provided by an embodiment of the present disclosure.

FIG. 2 is a schematic view showing a gate layer of the display panel provided by the embodiment of the present disclosure.

FIG. 3 is a schematic view showing a source/drain layer of the display panel provided by the embodiment of the present disclosure.

FIG. 4 is a schematic flowchart showing a manufacturing method of a display panel provided by an embodiment of the present disclosure.

### DESCRIPTION OF SPECIFIC EMBODIMENTS OF THE INVENTION

Hereinafter preferred embodiments of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

In the description of the present disclosure, it should be noted that unless there are express rules and limitations, the terms such as “mount,” “connect,” and “bond” should be comprehended in broad sense. For example, it can mean a permanent connection, a detachable connection, or an integrate connection; it can mean a mechanical connection, an electrical connection, or can communicate with each other; it can mean a direct connection, an indirect connection by an intermediate, or an inner communication or an interreaction between two elements. A person skilled in the art should understand the specific meanings in the present disclosure according to specific situations.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

The disclosure below provides many different embodiments or examples for realizing different structures of the present disclosure. In order to simplify the disclosure of the present disclosure, components and settings of specific examples are described below. Of course, they are only examples and are not intended to limit the present disclosure. Furthermore, reference numbers and/or letters may be repeated in different examples of the present disclosure. Such repetitions are for simplification and clearness, which per se do not indicate the relations of the discussed embodiments and/or settings. Moreover, the present disclosure provides examples of various specific processes and materials, but the applicability of other processes and/or application of other materials may be appreciated by a person skilled in the art.

The present disclosure provides a display panel and a manufacturing method thereof. The display panel may include:

an array substrate with a first protrusion defined thereon;

a color filter substrate disposed opposite to the array substrate;

a supporting structure disposed between the array substrate and the color filter substrate, wherein an end of the supporting structure is connected to a lateral side of the color filter substrate, and another end of the supporting structure is connected to a lateral side of the array substrate and abuts the first protrusion.

In the display panel provided by the present embodiment, the first protrusion is formed on the side of the array substrate near the color filter substrate. As a result, when the supporting structure of the color filter substrate is aligned and attached to the array substrate, the first protrusion can be embedded into the supporting structure, thereby preventing the supporting structure from being moved. Therefore, risk of alignment error is reduced, and abnormality of the display panel is prevented.

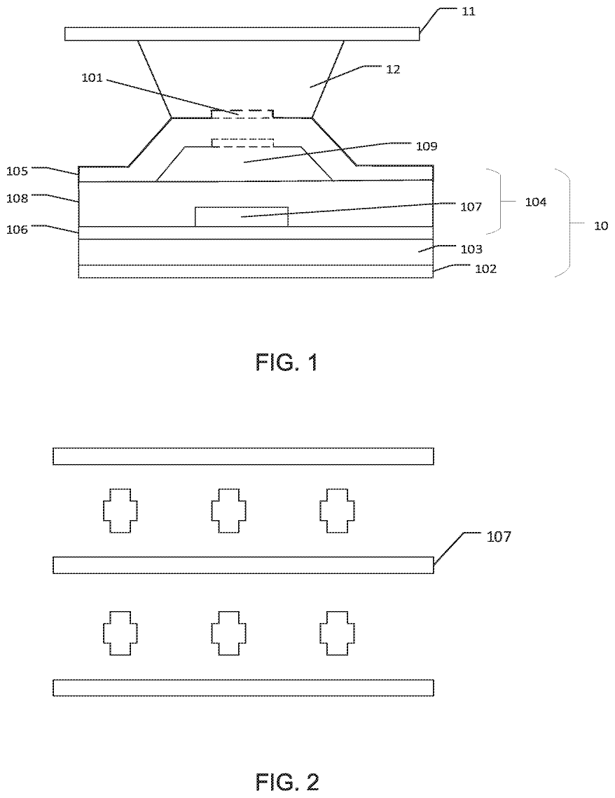

As shown in FIG. 1, a sectional view of the display panel of the present embodiment is provided. Specifically, in some embodiments, the display panel may include an array substrate 10 with a first protrusion 101 defined thereon, a color filter substrate 11 disposed opposite to the array substrate 10, and a supporting structure 12 disposed between the array substrate 10 and the color filter substrate 11. An end of the supporting structure 12 is connected to a lateral side of the color filter substrate 11, and another end of the supporting structure 12 is connected to a lateral side of the array substrate 10 and abuts the first protrusion 101. The supporting structure 12 is configured to support the color filter substrate 11, thereby reserving space between the color filter substrate 11 and the array substrate 10 for filling liquid crystals.

In the present embodiment, the first protrusion 101 is defined on a side of the array substrate 10 near the color filter substrate 11, and the supporting structure 12 is formed on a side of the color filter substrate 11 near the array substrate 10. The supporting structure 12 may be made of a flexible material. When the array substrate 10 and the color filter substrate 11 are attached to each other, the first protrusion 101 may be embedded into the supporting structure 12 by applying a certain force on the color filter substrate 11. Since the first protrusion 101 is embedded into the supporting structure 12, the supporting structure 12 is not easy to be moved. Therefore, compared with conventional technologies, stability of the display panel can be ensured.

In some embodiments, the array substrate 10 may further include a glass substrate 102; a buffer layer 103, wherein the buffer layer 103 is disposed on the glass substrate 102, thereby realizing a buffer function; a thin-film transistor (TFT) layer 104 disposed on the buffer layer 103; and a passivation layer 105 disposed on the TFT layer 104, wherein the first protrusion 101 is defined on the passivation layer 105. The passivation layer 105 completely covers the array substrate and has an exceptional capability to block moisture. Therefore, erosion can be prevented from occurring inside the array substrate, so that the display panel can be protected. Furthermore, the passivation layer 105 can also improve photoelectric performance parameters of the display panel.

In the above embodiments, the TFT layer 104 may include: an active layer (not shown in FIG. 1) disposed on the buffer layer 103; a gate insulating layer 106 disposed on the active layer, wherein the gate insulating layer 106 is configured to prevent an electrical connection between the gate insulating layer 106 and a gate layer 107, thereby preventing a display function from being affected; the gate layer 107 disposed on the gate insulating layer 106; an interlayer dielectric layer 108 disposed on the gate layer 107; and a source/drain layer 109 disposed on the interlayer dielectric layer 108.

In the present embodiment, when the gate layer 107 is formed on the gate insulating layer 106, at least one third protrusion (not shown in FIG. 1) is simultaneously formed. Specifically, when a plurality of gate lines are formed, the at least one third protrusion is formed with a mask plate. Please refer to FIG. 2, a schematic view showing the gate layer of the present embodiment is provided. In some embodiments, the gate layer 107 includes the gate lines, a plurality of gaps are defined between the gate lines, and the plurality of third protrusions are distributed in the gaps between the gate lines. Preferably, a number of the at least one third protrusion may be plural, and the third protrusions are evenly distributed in the gaps between the gate lines.

Please refer to FIG. 1 based on the above embodiments. Since FIG. 1 is the sectional view showing the display panel of the present disclosure, some structures of the display panel are blocked and cannot be shown. Therefore, some structures in FIG. 1 are not shown.

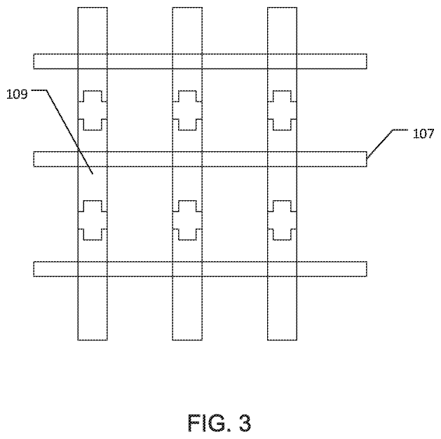

Please refer to FIG. 3, a schematic view showing the source/drain layer of the present embodiment is provided. After the interlayer dielectric layer 108 is formed, the source/drain layer 109 is formed on the interlayer dielectric layer 108. Please refer to FIG. 1 and FIG. 3, a plurality of fourth protrusions are formed on positions on the interlayer dielectric layer 108 corresponding to the third protrusions, a plurality of second protrusions are formed on positions on the source/drain layer corresponding to the fourth protrusions. Shapes of the second protrusions and shapes of the fourth protrusions are same, and positions of the second protrusions correspond to positions of the fourth protrusions.

In the above embodiments, the passivation layer 105 is formed on the source/drain layer 109 and completely covers the source/drain layer 109. The plurality of first protrusions 101 are formed on positions on the passivation layer 105 corresponding to the second protrusions. Shapes of the second protrusions and shapes of the first protrusions are same, positions of the second protrusions correspond to positions of the first protrusions 101, and the first protrusions 101 are defined on a side of the passivation layer 105 away from the source/drain layer 109.

In the present embodiment, the first protrusions 101 are formed on a side of the array substrate 10 near the color filter substrate 11. Specifically, the first protrusions 101 are formed on the side of the passivation layer 105 near the color filter substrate 11. Therefore, when the array substrate 10 and the color filter substrate 11 are aligned and attached to each other, the first protrusions 101 can abut and fix the supporting structure 12, thereby preventing the supporting structure 12 from being moved.

In some embodiments, a plurality of recesses may be formed on a side of the supporting structure 12 near the array substrate 10, and the protrusions may be embedded into the recesses. Specifically, the first protrusions 101 may be embedded into the recesses defined on the supporting structure 12. The supporting structure is connected to the array substrate 10 and the color filter substrate 11 by the recesses and the first protrusions 101. Shapes of the first protrusions 101 correspond to shapes of the recesses, thereby allowing the first protrusions to be fully embedded into the recesses. Because the recesses are defined on the supporting structure 12, the first protrusions 101 can be embedded into the recesses. As a result, the supporting structure 12 can be prevented from being moved by engaging the protrusions with the recesses.

In the present embodiment, structures of the protrusions are not limited, and may be cuboid, cylindrical, or criss-crossing.

In the present embodiment, the array substrate 10 may further include: a first insulating layer disposed on the source/drain layer; and a common electrode layer disposed on the first insulating layer. The common electrode layer is disposed on the first insulating layer and is disposed under the passivation layer 108. Furthermore, the array substrate 10 includes a pixel electrode layer disposed on the passivation layer 108. The insulating layer, the common electrode layer, and the pixel electrode layer are not shown in FIG. 1.

In some embodiments, the array substrate may include the gate layer and the source/drain layer. The gate layer includes the gate lines and a plurality of fifth protrusions, the source/drain layer is disposed on the fifth protrusions, thereby forming the first protrusions on positions on the source/drain layer corresponding to the fifth protrusions. The first protrusions abut the supporting structure 12. In other words, the first protrusions are connected to the supporting structure, thereby connecting the array substrate 10 to the color filter substrate 11.

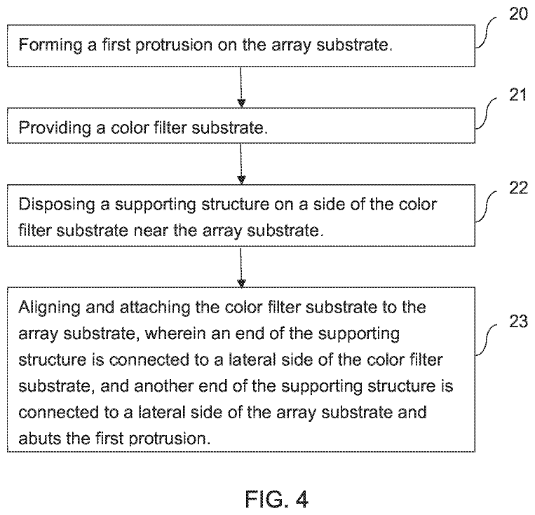

The present disclosure further provides a manufacturing method of a display panel. As shown in FIG. 4, a flowchart showing the manufacturing method of the display panel of the present embodiment is provided. The manufacturing method includes:

20, forming a first protrusion on the array substrate;

21, providing a color filter substrate;

22, disposing a supporting structure on a side of the color filter substrate near the array substrate; and

23, aligning and attaching the color filter substrate to the array substrate, wherein an end of the supporting structure is connected to a lateral side of the color filter substrate, and another end of the supporting structure is connected to a lateral side of the array substrate and abuts the first protrusion.

The present disclosure provides the manufacturing method of the display panel. In the display panel, the first protrusion is formed on the side of the array substrate near the color filter substrate. As a result, when the supporting structure of the color filter substrate is aligned and attached to the array substrate, the first protrusion can be embedded into the supporting structure, thereby preventing the supporting structure from being moved. Therefore, risk of alignment error is reduced, and abnormality of the display panel is prevented.

In some embodiments, the step of forming the first protrusion on the array substrate may include: providing a glass substrate; forming a buffer layer on the glass substrate; forming a gate layer on the buffer layer, wherein the gate layer includes a gate line and a third protrusion; forming a source/drain layer on the gate layer, thereby forming a second protrusion on a position on the source/drain layer corresponding to the third protrusion; and forming a passivation layer on the source/drain layer, thereby forming the first protrusion layer on the passivation layer.

Specifically, in some embodiments, the array substrate may be formed by eight-mask technologies. Specifically, multiple structures of the array substrate are respectively formed with eight mask plates. Specific procedures are described below: first, providing a glass substrate, depositing a light-shielding film layer on the glass substrate, and etching the light-shielding film layer to form a light-shielding layer pattern, thereby forming a light-shielding layer. After that, a buffer layer must be deposited on the light-shielding layer.

In the above embodiments, after the buffer layer is formed, a layer of amorphous silicon (a-Si) material is deposited on the buffer layer. Then, the a-Si material is annealed by laser radiation to form polysilicon (poly-Si). After that, the poly-Si is patterned, thereby obtaining a patterned poly-Si which is the active layer of the array substrate. After the active layer is formed, a gate insulating layer must be formed on the active layer. Then, a gate layer is formed on the gate insulating layer. The gate insulating layer is disposed between the active layer and the gate layer, thereby preventing an electrical connection between the active layer and the gate layer. The gate layer and a third protrusion are formed at the same time. The gate layer is formed from a plurality of gate lines, a plurality of gaps are defined between the gate lines, and the plurality of third protrusions are formed in the gaps between the gate lines. The gate lines and the third protrusions are formed at the same time by the same mask plate.

Specifically, the gate layer can be formed on the active layer by a series of processes including exposure, dry etching, and stripping.

After the gate layer is formed, an interlayer dielectric layer must be formed on the gate layer. The interlayer dielectric layer covers the gate layer. When the interlayer dielectric layer is formed, a plurality of fourth protrusions are formed on positions on the interlayer dielectric layer corresponding to the third protrusions. After the interlayer dielectric layer is formed, a plurality of through-holes must be formed on the interlayer dielectric layer.

Based on the above embodiments, after the through-holes on the interlayer dielectric layer are formed, a source/drain layer must be formed on the interlayer dielectric layer. The source/drain layer is formed on the fourth protrusions and completely covers the fourth protrusions. Therefore, after the source/drain layer is formed, a plurality of second protrusions are formed on a side of the source/drain layer away from the interlayer dielectric layer and correspond to the fourth protrusions. After the source/drain layer is formed, a plurality of through-holes must be formed on the source/drain layer. The source/drain layer is connected to the active layer by the through-holes of the source/drain layer.

After the source/drain layer is formed, a passivation layer must be formed on the source/drain layer. Because the second protrusions are formed on the source/drain layer, the first protrusions are formed on positions on the passivation layer corresponding to the second protrusions when the passivation layer is formed.

In some embodiments, a first insulating layer must be formed on the source/drain layer. After the first insulating layer is formed, an electrode layer must be formed. A common electrode layer is formed on the first insulating layer. After that, another passivation layer and a pixel electrode layer are sequentially formed on the common electrode layer.

It should be noted that the display panel and the manufacturing method thereof not only can be applied to display panels formed with eight mask plates, but also can be applied to other display panels such as display panels formed with five mask plates or display panels formed with six mask plates.

In the present embodiment, for methods of manufacturing other layers of the array substrate, please refer to the step of forming the gate layer or conventional technologies, and no limitations will be made here.

In the above embodiments, the focus of each embodiment is different, and for a part that is not detailed in an embodiment, reference may be made to related descriptions of other embodiments.

A display panel and a manufacturing thereof have been described in detail with embodiments provided by the present disclosure, which illustrate principles and implementations thereof. However, the description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

What is claimed is:

1. A display panel, comprising:
an array substrate with a first protrusion defined thereon;
a color filter substrate disposed opposite to the array substrate; and
a supporting structure disposed between the array substrate and the color filter substrate, wherein an end of the supporting structure is connected to a lateral side of the color filter substrate, and another end of the supporting structure is connected to a lateral side of the array substrate and abuts the first protrusion.

2. The display panel of claim 1, wherein the array substrate further comprises:
a glass substrate;
a buffer layer disposed on the glass substrate;
a thin-film transistor (TFT) layer disposed on the buffer layer; and
a passivation layer disposed on the TFT layer, wherein the first protrusion is defined on the passivation layer.

3. The display panel of claim 2, wherein the TFT layer comprises:
an active layer;
a gate insulating layer disposed on the active layer;
a gate layer disposed on the gate insulating layer;
an interlayer dielectric layer disposed on the gate layer; and
a source/drain layer disposed on the interlayer dielectric layer.

4. The display panel of claim 3, wherein a second protrusion is defined on the source/drain layer, and the passivation layer covers the source/drain layer, thereby forming the first protrusion on a position on the passivation layer corresponding to the second protrusion.

5. The display panel of claim 4, wherein the gate layer comprises a gate line and a third protrusion, and the source/drain layer covers the third protrusion, thereby forming the second protrusion on a position on the source/drain layer corresponding to the third protrusion.

6. The display panel of claim 1, wherein a recess is defined on a side of the supporting structure near the array substrate and corresponds to the first protrusion, and the supporting structure abuts the array substrate by engaging the recess with the first protrusion.

7. The display panel of claim 1, wherein the array substrate comprises a gate layer and a source/drain layer, the source/drain layer is disposed on the gate layer, and the first protrusion is defined on the source/drain layer.

8. The display panel of claim 1, wherein the first protrusion has a criss-crossing structure.

9. A method of manufacturing a display panel, comprising following steps:
forming a first protrusion on the array substrate;
providing a color filter substrate;
disposing a supporting structure on a side of the color filter substrate near the array substrate; and
aligning and attaching the color filter substrate to the array substrate, wherein an end of the supporting structure is connected to a lateral side of the color filter substrate, and another end of the supporting structure is connected to a lateral side of the array substrate and abuts the first protrusion.

10. The method of claim 9, wherein the step of forming the first protrusion on the array substrate comprises following steps:
providing a glass substrate;
forming a buffer layer on the glass substrate;
forming a gate layer on the buffer layer, wherein the gate layer comprises a gate line and a third protrusion;
forming a source/drain layer on the gate layer, wherein a second protrusion is formed on a position on the source/drain layer corresponding to the third protrusion; and
forming a passivation layer on the source/drain layer, thereby forming the first protrusion on the passivation layer.
